(19) United States
(12) Patent Application Publication
(10) Pub. No.: US 2016/0033782 A1
(43) Pub. Date: Feb. 4, 2016

(54) DUAL-FIELD DISPLAY SYSTEM

(71) Applicant: BOE TECHNOLOGY GROUP CO., LTD., Beijing (CN)

(72) Inventor: Jiliang WANG, Beijing (CN)

(21) Appl. No.: 14/424,776

(22) PCT Filed: Mar. 25, 2014
(86) PCT No.: PCT/CN2014/074036

§ 371 Date: Feb. 27, 2015

(30) Foreign Application Priority Data
Feb. 13, 2014 (CN) 201410050375.9

(51) Int. Cl. G02B 27/26; H01L 51/52; G02B 5/30

(52) U.S. Cl. CPC G02B 27/26; G02B 5/3083; H01L 51/5293

(57) ABSTRACT

A dual-field display system provided by the present invention comprises: a display unit including a display panel divided into a first and a second display regions, the first display region emitting a first polarized light with a first polarization direction, the second display region emitting a second polarized light with a second polarization direction different from the first polarization direction; at least one pair of first glasses comprising a left lens and a right lens, the left lens and the right lens each comprising a first polarizer for allowing the first polarized light to transmit therethrough and blocking the second polarized light; and at least one pair of second glasses comprising a left lens and a right lens, the left lens and the right lens each comprising a second polarizer for allowing the second polarized light to transmit therethrough and blocking the first polarized light.

### FIELD OF THE INVENTION

The present invention relates to the field of dual-field display technology, and particularly relates to a dual-field display system.

### BACKGROUND OF THE INVENTION

The dual-field display refers to a technology capable of displaying two different images at the same moment by using the same display screen.

The present dual-field display is mainly realized by an optical grating. As shown in FIG. 1 and FIG. 2, a display screen is divided into a first display region 11 and a second display region 12. The two display regions are respectively composed of strip-shaped regions arranged alternately, and each of the strip-shaped regions is corresponding to one or more columns of pixels (each pixel may include a plurality of sub-pixels). A slit grating 9 including alternating shading strips and light transmitting strips is provided in front of the display screen. Due to the function of the shading strips, in a left visual region 91 on the left side of the screen, only the content of the first display region 11 can be watched (the second display region 12 is blocked), while in a right visual region 92 on the right side of the screen, only the content of the second display region 12 can be watched (the first display region 11 is blocked), so that the purpose of simultaneously displaying two different images on one display screen is realized.

The inventor has found that the present dual-field display technology has at least the following disadvantages:

First, due to the limitations of the technological level, size, shape and the like of an optical grating are limited, so the dual-field display technology using an optical grating is mainly applicable to display screens having large pixels and regular pixel arrangement (e.g., arranged into a matrix). However, at present, with higher and higher resolution of a display screen, particularly for an Organic Light-Emitting Diode (OLED) display screen with high resolution, the size of pixels has become smaller and smaller, so that the size of the optical grating is difficult to adapt to the size of pixels. In addition, there are also many display screens with incompletely regular pixel arrangements (e.g., pixels in different rows may be staggered for a certain distance), so the optical grating is difficult to be processed into corresponding shape.

Second, it can be seen from the principle of a grating dual-field display technology that dual-field effects is realized only when a user is necessarily at a particular position (a left visual region 91 or right visual region 92 as shown in FIG. 2) within a relatively small area, so that the visual range is narrow and the number of audiences is limited. In addition, the user cannot move at will while watching, and also can not select desired pictures at will (for example, the user only can watch the image in the first display region when being located within the left visual region, and has to move to the right visual region if he or she wants to watch the image in the second display region), so the flexibility in use is poor.

### SUMMARY OF THE INVENTION

Technical problems to be solved by the present invention include that the present dual-field display technology is difficult to adapt to display devices with high resolution or irregular pixel arrangement, the visual range is narrow, flexibility in use is poor and the like. Thus, the present invention provides a dual-field display system applicable to various display devices and having large visual range and high flexibility in use.

A technical solution employed to solve the technical problem of the present invention is a dual-field display system, comprising:

a display unit including a display panel divided into a first display region and a second display region, the first display region emitting a first polarized light with a first polarization direction, the second display region emitting a second polarized light with a second polarization direction different from the first polarization direction;

at least one pair of first glasses including a left lens and a right lens, the left lens and the right lens of the first glasses each including a first polarizer for allowing the first polarized light to transmit therethrough and blocking the second polarized light; and

at least one pair of second glasses including a left lens and a right lens, the left lens and the right lens of the second glasses each including a second polarizer for allowing the second polarized light to transmit therethrough and blocking the first polarized light.

According to an embodiment of the present invention, the display unit may further include an emergent light polarizer provided outside a light exiting surface of the display panel and including a first emergent light polarizer and a second emergent light polarizer, the first emergent light polarizer being provided within the first display region and having a first emergent polarization direction, the second emergent light polarizer being provided within the second display region and having a second emergent polarization direction, the first emergent polarization direction being vertical to the second emergent polarization direction. Both of the first polarizer and the second polarizer may be linear polarizer, the polarization direction of the first polarizer is parallel to the first emergent polarization direction, and the polarization direction of the second polarizer is parallel to the second emergent polarization direction.

According to an embodiment of the present invention, the display unit may further include: an emergent light polarizer provided outside a light exiting surface of the display panel and including a first emergent light polarizer and a second emergent light polarizer, the first emergent light polarizer being provided within the first display region and having a first emergent polarization direction, the second emergent light polarizer being provided within the second display region and having a second emergent polarization direction, the first emergent polarization direction being vertical to the second emergent polarization direction; and a wave plate provided outside the emergent light polarizer, the wave plate being a ¼ wave plate or a ¾ wave plate, both of the included angle between the optical axis of the wave plate and the first emergent polarization direction and the included angle between the optical axis of the wave plate and the second emergent polarization direction being 45 degree. One of the first polarizer and the second polarizer may be a left-handed circular polarizer, and the other one of the first polarizer and the second polarizer may be a right-handed circular polarizer.

According to an embodiment of the present invention, the display unit may further include: an emergent light polarizer provided outside a light exiting surface of the display panel; and a wave plate provided outside the emergent light polarizer and including a ¼ wave plate and a ¾ wave plate, the ¼ wave plate being provided within one of the first display region and the second display region, the ¾ wave plate being provided within the other one of the first display region and the second display region, and the included angles between the optical axes of the wave plates and the polarization direction of the emergent light polarizer being 45 degree. One of the first polarizer and the second polarizer may be a left-handed circular polarizer, and the other one of the first polarizer and the second polarizer may be a right-handed circular polarizer.

According to an embodiment of the present invention, the display panel may be a liquid crystal display panel, and further includes a backlight and an incident light polarizer. The backlight may be provided outside a light receiving surface of the liquid crystal display panel, and the incident light polarizer may be provided between the backlight and the liquid crystal display panel. In this case, the incident light polarizer may include a first incident light polarizer and a second incident light polarizer, the first incident light polarizer is provided within the first display region and has a first incident polarization direction, the second incident light polarizer is provided within the second display region and has a second incident polarization direction, and the first incident polarization direction is vertical to the second incident polarization direction.

According to an embodiment of the present invention, the display panel may be an organic light-emitting diode display panel.

According to an embodiment of the present invention, the first display region may include a plurality of parallel first strip-shaped sub-regions, and the second display region may include a plurality of parallel second strip-shaped sub-regions. The plurality of first strip-shaped sub-regions and the plurality of second strip-shaped sub-regions may be arranged alternately in parallel to each other. In this case, the length direction of the first strip-shaped sub-regions and the second strip-shaped sub-regions may be parallel to the row direction of the display panel. Alternatively, the length direction of the first strip-shaped sub-regions and the second strip-shaped sub-regions may be parallel to the column direction of the display panel. Preferably, each of the first strip-shaped sub-regions and the second strip-shaped sub-regions is a row or column of pixels of the display panel.

According to an embodiment of the present invention, the first display region may include a plurality of first rectangular sub-regions, and the second display region may include a plurality of second rectangular sub-regions. The first rectangular sub-regions and the second rectangular sub-regions may be the same in size, and the plurality of first rectangular sub-regions and the plurality of second rectangular sub-regions may be arranged into a matrix. In each row of the matrix, the first rectangular sub-regions and the second rectangular sub-regions are arranged alternately, and in each column of the matrix, the first rectangular sub-regions and the second rectangular sub-regions are arranged alternately.

The dual-field display system provided by the present invention realizes dual-field display by selectively transmitting the polarized light. As the selection of the polarized light does not require that a user is located at a particular position, the visual range of the dual-field display system is not limited, and there may be many audiences (as long as more pairs of glasses are provided for more audiences). Moreover, the user may select desired pictures at will (just needing to replace the worn glasses), so the flexibility in use is high. As polarizer in different polarization directions may be realized by high-precision laser processing or other ways, resolution, form and the like of the polarizer are not limited, so that dual-field display system provided by the present invention is applicable to display devices with high resolution and irregular pixel arrangement.

### BRIEF DESCRIPTION OF THE DRAWINGS

FIG. 1 is a distribution diagram of display regions of a conventional dual-field display device;

FIG. 2 is a schematic diagram of the display principle of a conventional grating dual-field display device;

FIGS. 3-5 are schematic diagrams showing various distributions of display regions of the dual-field display system according to embodiments of the present invention;

FIGS. 6-9 are schematic diagrams of the display principle of the dual-field display system according to an embodiment of the present invention; and

FIGS. 10-12 are schematic diagrams of the display principle of the dual-field display system according to another embodiment of the present invention.

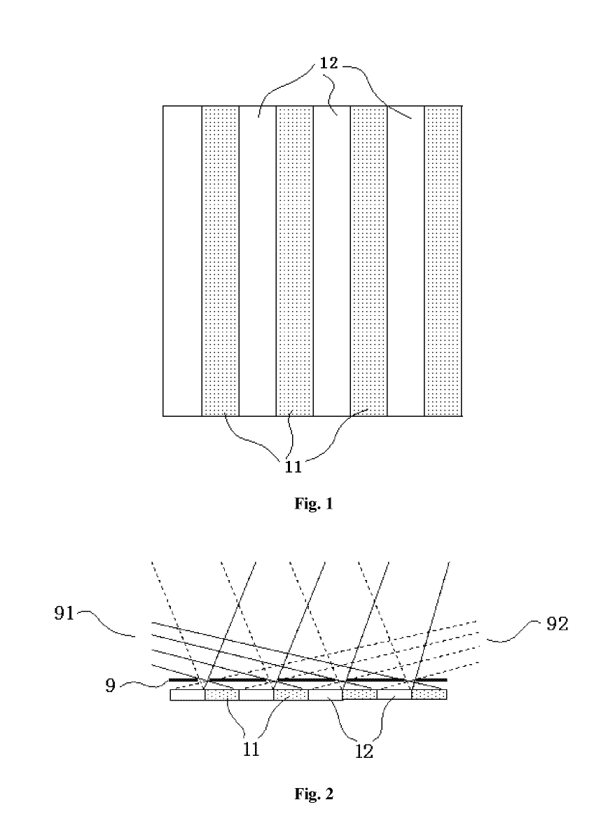

Reference numerals: 1—Display panel; 11—First display region; 12—Second display region; 2—Emergent light polarizer; 21—First emergent light polarizer; 22—Second emergent light polarizer; 3—Wave plate; 31—¼ wave plate; 32—¾ wave plate; 5—Backlight; 6—Incident light polarizer; 61—First incident light polarizer; 62—Second incident light polarizer; 7—Display unit; 81—First glasses; 811—First polarizer; 82—Second glasses; 821—Second polarizer; 9—Slit grating; 91—Left visual region; and, 92—Right visual region.

### DETAILED DESCRIPTION OF THE EMBODIMENTS

To make those skilled in the art better understand the technical solutions of the present invention, the present invention will be further described below in details with reference to the accompanying drawings and the specific implementations.

FIGS. 6-9 are schematic diagrams of the display principle of the dual-field display system according to an embodiment of the present invention. Referring to FIG. 6, the dual-field display system according to an embodiment of the present invention may include a display unit 7, at least one pair of first glasses 81 and at least one pair of second glasses 82.

The display unit 7 includes a display panel 1 for displaying and divided into a first display region 11 and a second display region 12. The first display region 11 emits a first polarized light having a first polarization direction, while the second display region 12 emits a second polarized light having a second polarization direction different from the first polarization direction. In drawings, the polarization directions of light are exemplarily shown by double-headed arrows, but the present invention is not limited thereto. For example, the polarization directions of light may be different from the directions shown in drawings.

The first glasses 81 include a left lens and a right lens, and each of the left lens and the right lens includes a first polarizer 811. The first polarizer 811 allows the first polarized light to transmit therethrough and blocks the second polarized light. Similarly, the second glasses 82 include a left lens and a right lens, and each of the left lens and the right lens includes a second polarizer 821. The second polarizer 821 allows the second polarized light to transmit therethrough and blocks the first polarized light.

In other words, the first glasses 81 only allow the first polarized light exiting from the first display region to transmit therethrough, so only the content of the first display region 11 can be watched by the first glasses 81; and the second glasses 82 only allow the second polarized light exiting from the second display region 12 to transmit therethrough, so only the content of the second display region 12 can be watched by the second glasses 82. In this way, by wearing different pairs of glasses, different users may watch different images on one display screen at the same time, thereby realizing dual-field display.

In the dual-field display system according to the present invention, the dual-field display is realized by selectively transmitting the polarized light. As the selection of the polarized light does not require that a user is located at a particular position, the visual range of the dual-field display system is not limited, and there may be many audiences (as long as more pairs of glasses are provided for more audiences). Moreover, the user may select desired pictures at will (only needing to replace the worn glasses), so the flexibility in use is high. As polarizer in different polarization directions may be realized by high-precision laser processing or other ways, resolution, form and the like of the polarizer are not limited, so that dual-field display system provided by the present invention is applicable to display devices with high resolution and irregular pixel arrangement.

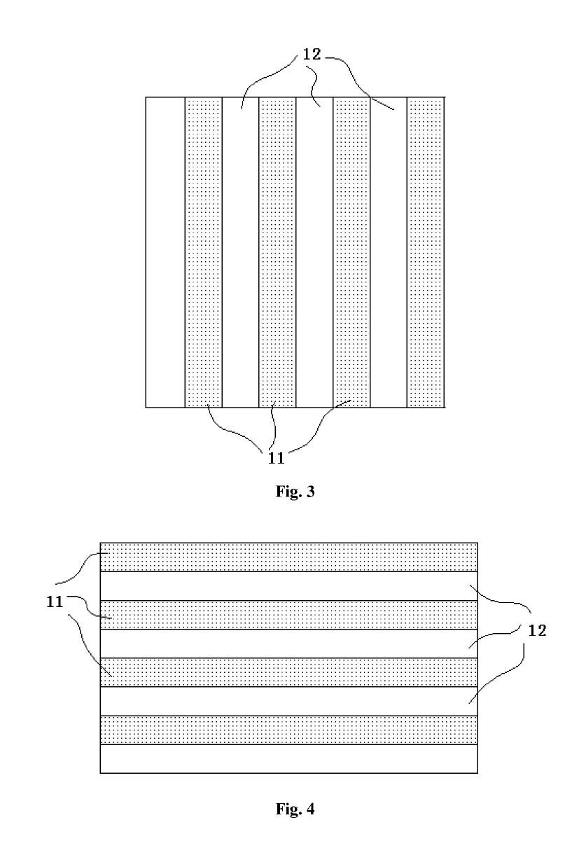

FIGS. 3-5 show diagrams of various distributions of display regions of the dual-field display system according to embodiments of the present invention. As shown in FIGS. 3-5, the division of the first display region 11 and the second display region 12 may be diverse.

For example, as shown in FIG. 3, the first display region 11 may include a plurality of parallel first strip-shaped sub-regions, and the second display region 12 may include a plurality of parallel second strip-shaped sub-regions. The plurality of first strip-shaped sub-regions and the plurality of second strip-shaped sub-regions may be arranged alternately in parallel to each other.

In other words, a light exiting surface of the display unit 7 may be divided into a plurality of parallel and adjacent strip-shaped sub-regions, and the strip-shaped sub-regions belonging to different display regions are arranged alternately.

As shown in FIG. 3, the length direction of each of the strip-shaped sub-regions may be parallel to the row direction of the display panel 1. Alternatively, as shown in FIG. 4, the length direction of each of the strip-shaped sub-regions may be parallel to the column direction of the display panel 1.

In other words, the strip-shaped sub-regions may be arranged transversely or longitudinally. In this way, it is advantageous for the division of the display regions, and the image processing becomes simpler.

When the length direction of each of the strip-shaped sub-regions is parallel to the row direction of the display panel 1, each of the strip-shaped sub-regions may be a row of pixels of the display panel 1; and when the length direction of each of the strip-shaped sub-regions is parallel to the column direction of the display panel 1, each of the strip-shaped sub-regions may be a column of pixels of the display panel 1.

In other words, the strip-shaped sub-regions may be divided in pixels. In this way, each of the strip-shaped sub-regions may independently display the required content, and the width of the strip-shaped sub-regions is the smallest (the size of one pixel), so that each picture displayed by the display unit 7 may be relatively clear. However, the present invention is not limited thereto. For example, each of the strip-shaped sub-regions may include a plurality of pixels in width.

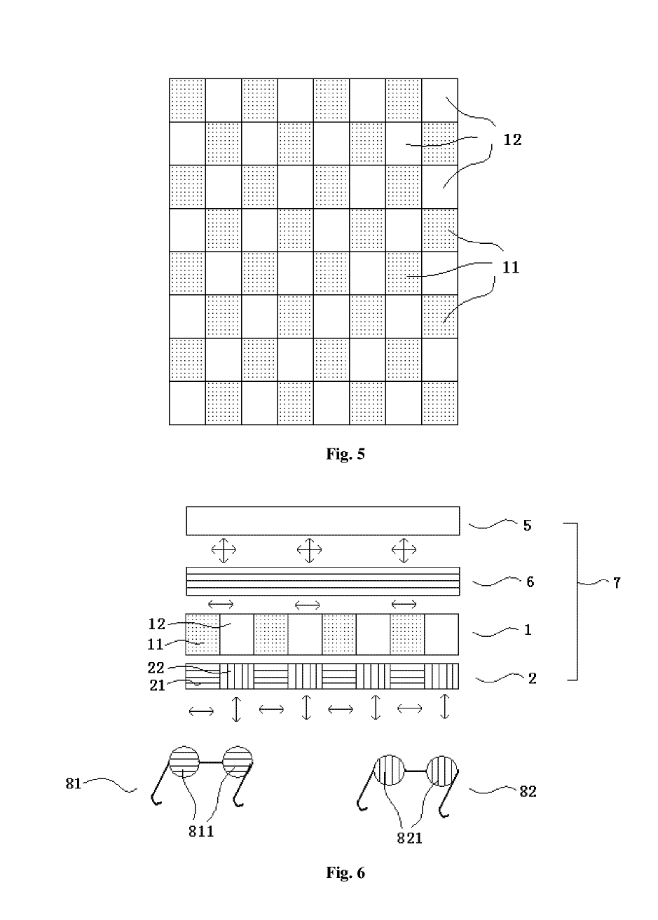

Alternatively, as shown in FIG. 5, the first display region 11 and the second display region 12 may include a plurality of rectangular sub-regions respectively. The rectangular sub-regions may be the same in size and are arranged into a matrix. In each row of the matrix, the rectangular sub-regions of the first display region 11 and the second rectangular sub-regions of the second display region 12 are arranged alternately; and in each column of the matrix, the rectangular sub-regions of the first display region 11 and the second rectangular sub-regions of the second display region 12 are arranged alternately. Each of the rectangular sub-regions may be only one pixel, but the present invention is not limited thereto. For example, the rectangular sub-regions may be divided in form of 1×2, 2×2, 2×3 and so on.

In other words, the first display region 11 and the second display region 12 may consist of rectangular sub-regions, and the rectangular sub-regions of different display regions are alternately arranged in both the row direction and the column direction of the display panel 1, so that the rectangular sub-regions of different display regions are arranged in a form like an international chess board.

Referring to FIG. 6 again, the display unit 7 includes a display panel 1. In this embodiment, the display panel 1 may be a liquid crystal display panel. In this case, the display unit 7 further includes a backlight 5 disposed outside a light receiving surface of the liquid crystal display panel and used for providing lighting for the liquid crystal display panel. An incident light polarizer 6 is provided between the backlight 5 and the liquid crystal display panel, and an emergent light polarizer 2 is provided outside a light exiting surface of the display panel 1.

It can be seen from the basic display principle of a liquid crystal display panel that the purpose of display can be realized only by arranging linear polarizers outside both the light receiving surface and the light exiting surface.

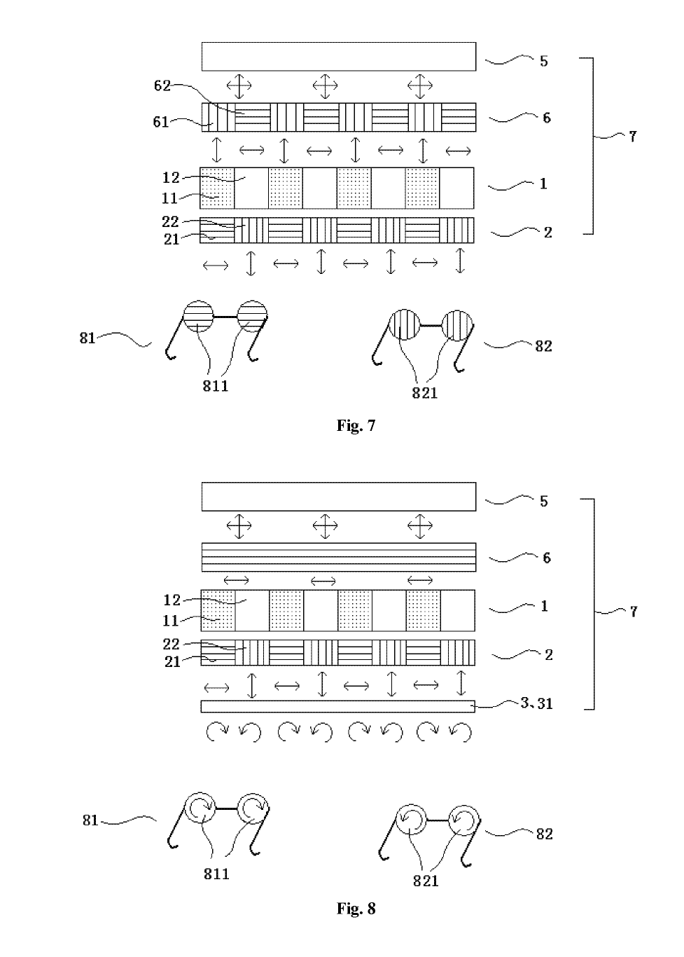

According to an implementation of this embodiment, as shown in FIG. 6 and FIG. 7, the emergent light polarizer 2 includes a first emergent light polarizer 21 and a second emergent light polarizer 22. The first emergent light polarizer 21 is provided within the first display region 11 and has a first emergent polarization direction, and the second emergent light polarizer 22 is provided within the second display region 12 and has a second emergent polarization direction. The first emergent polarization direction is vertical to the second emergent polarization direction. In this case, the first polarizer 811 of the first glasses 81 is a linear polarizer, and the polarization direction of the first polarizer is parallel to the first emergent polarization direction; and the second polarizer 821 of the first glasses 81 is a linear polarizer, and the polarization direction of the second polarizer is parallel to the second emergent polarization direction.

According to the above implementation, the light emitted by the backlight 5 becomes a linear polarized light having a particular polarization direction after passing through the incident light polarizer 6. Then, the linear polarized light enters the liquid crystal display panel, and the polarization direction of the linear polarized light has different changes at different positions (i.e., at different sub-pixel positions) under the action of the liquid crystal display panel. The linear polarized light exiting from the liquid crystal display panel will pass through the emergent light polarizer 2. According to this embodiment, the linear polarized light passing through the first emergent light polarizer 21 provided within the first display region 11 becomes a first polarized light having a first polarization direction (the first polarization direction is parallel to the first emergent polarization direction); and the linear polarized light passing through the second emergent polarizer 22 provided within the second display region 12 becomes a second polarized light having a second polarization direction (the second polarization direction is parallel to the second emergent polarization direction). As the first emergent polarization direction is vertical to the second emergent polarization direction, the first polarization direction is vertical to the second polarization direction, that is, the polarization direction of the first polarized light is vertical to the polarization direction of the second polarized light.

Therefore, the first glasses 81 including the first polarizer 811 (its polarization direction is parallel to the first emergent polarization direction, i.e., parallel to the first polarization direction of the first polarized light) may transmit the first polarized light exiting from the first display region 11 and block the second polarized light exiting from the second display region 12, and the second glasses 82 including the second polarizer 821 (its polarization direction is parallel to the second emergent polarization direction, i.e., parallel to the second polarization direction of the second polarized light) may transmit the second polarized light exiting from the second display region 12 and block the first polarized light exiting from the first display region 11, so that the pictures in different display regions may be watched by the first glasses 81 and the second glasses 82 respectively, thereby realizing duel-field display.

In addition, the emergent light polarizer 2 filters linear polarized light exiting from different positions (different sub-pixels) to different degrees, so that the basic display function is realized.

In the dual-field display system according to this implementation, in comparison to a conventional liquid crystal display device, in addition to the basic display function, the emergent light polarizer 2 also enable light exiting from different display regions to have different polarization directions, so as to realize dual-field display.

According to an implementation of this embodiment, as shown in FIG. 6, the incident light polarizer 6 may have the same polarization direction in various display regions, so that the manufacturing process of the incident light polarizer 6, an orientation layer of the liquid crystal display panel and the like becomes simpler. On the other hand, as the included angle between the polarization direction of the incident light polarizer 6 and the polarization direction of the emergent light polarizer 2 is different in different display regions (for example, as shown in FIG. 6, the included angle between them is 0 degree in the first display region, while the included angle between them is 90 degrees in the second display region), when two pixels in different display regions need to display the same content, the voltage applied thereto should be different, so that it is required to adjust the driving mode of the liquid crystal display panel.

Alternatively, as shown in FIG. 7, the incident light polarizer 6 may include a first incident light polarizer 61 and a second incident light polarizer 62. The first incident light polarizer 61 is provided within the first display region 11 and has a first incident polarization direction vertical to the first emergent polarization direction, and the second incident light polarizer 62 is provided within the second display region 12 and has a second incident polarization direction vertical to the second emergent polarization direction. In other words, the incident light polarizer 6 has different polarization directions in different display regions, and the polarization direction of the incident light polarizer 6 is vertical to the polarization direction of the emergent light polarizer 2 in the same display region. As the polarization direction of the incident light polarizer is vertical to that of the emergent light polarizer in a convention liquid crystal display device, it is not required to adjust the driving mode.

According to another implementation of this embodiment, as shown in FIG. 8, a wave plate 3 may be provided outside the emergent light polarizer 2. The wave plate 3 may be a ¼ wave plate 31 or a ¾ wave plate 32 (FIG. 8 shows an example of the ¼ wave plate 31), and both of the included angle between the optical axis of the wave plate 3 and the first emergent polarization direction and the included angle between the optical axis of the wave plate 3 and the second emergent polarization direction are 45 degree. In this case, one of the first polarizer 811 and the second polarizer 821 in the two pairs of glasses 81 and 82 is a left-handed circular polarizer, while the other one is a right-handed circular polarizer.

According to the above implementation, as the polarization directions of the linear polarized light exiting from the first emergent light polarizer 21 and the second emergent light polarizer 22 respectively provided within the first display region 11 and the second display region 12 are vertical to each other, and the included angles between their polarization directions and the optical axis of the wave plate 3 are 45 degree (but opposite in direction), one of the linear polarized light is transformed into a left-handed circular polarized light while the other one is transformed into a right-handed circular polarized light (the specific transformation way is determined according to the direction of the included angle) after passing through the wave plate 3. Therefore, the light exiting from the two display regions 11 and 12 become circular polarized light having opposite rotation directions (i.e., polarized light having different polarization directions). A user may watch images of different display regions by two pairs of glasses with circular polarizers having different rotation directions, thereby realizing dual-field display.

Those skilled in the art should understand that, the ¼ wave plate, the ¾ wave plate and the like are all corresponding to light of particular wavelengths. As the present invention is aimed at displaying, the wave plate 3 should be corresponding to a central wavelength (580 nm) of the wavelength range of a visual light (390 nm-770 nm). In this case, the visual light within other ranges generates an elliptically polarized light rather than an absolutely circular polarized light after passing through the wave plate 3, so certain light leakage will be generated in the glasses. However, this does not influence the implementation of the basic principle of the present invention.

According to this implementation, the dual-field display is realized by the circular polarized light, but the filtering of the circular polarized light will not be influenced by the change in the angle of the polarizer, so the dual-field display system realized in this way is more convenient to use, and the display performance will not be affected even though a user wearing the glasses shakes his or her head or does other actions.

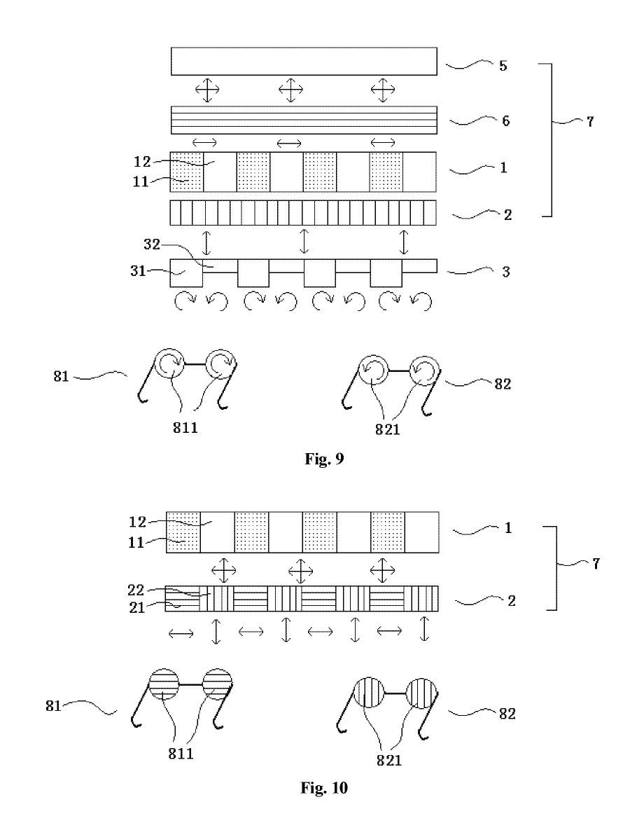

According to another implementation of this embodiment, as shown in FIG. 9, the emergent light polarizer 2 may have the same polarization direction in different display regions. Correspondingly, the wave plate 3 includes a ¼ wave plate 31 and a ¾ wave plate 32. The ¼ wave plate 31 is provided within one of the first display region 11 and the second display region 12, while the ¾ wave plate 32 is provided within the other one of the first display region 11 and the second display region 12. The included angle between the optical axis of the wave plate 3 and the polarization direction of the emergent light polarizer 2 is 45 degree. In addition, the implementation shown in FIG. 9 is fundamentally the same as the implementation shown in FIG. 8.

In this case, the linear polarized light exiting from the emergent light polarizer 2 has the same polarization direction, and the included angle between the polarization direction and the optical axis of the wave plate 3 is 45 degree. The linear polarized light will be respectively transformed into a left-handed circular polarized light and a right-handed circular polarized light (the specific transformation way is determined by the direction of the included angle) after respectively passing through the ¼ wave plate 31 and the ¾ wave plate 32, so the light exiting from the two display regions 11 and 12 become circular polarized light having opposite rotation directions (i.e., polarized light having different polarization directions). A user may watch images of different display regions by two pairs of glasses with circular polarizers having different rotation directions, thereby realizing dual-field display. In this implementation, the light exiting from the display unit 7 is transformed into different circular polarized light by using the ¼ wave plate 31 and ¾ wave plate 32 having different thicknesses.

FIGS. 10-12 are schematic diagrams of the display principle of a dual-field display system according to another embodiment of the present invention. Referring to FIG. 10, similar to the above embodiment, the dual-field display system according to this embodiment may include a display unit 7, at least one pair of first glasses 81 and at least one pair of second glasses 82.

The difference between this embodiment and the above embodiment is that, in this embodiment, the display panel 1 may be an Organic Light-Emitting Diode (OLED) display panel for emitting a light (circular polarized light) of the desired brightness. Hereby, FIGS. 10-12 show various implementations of this embodiment corresponding to different implementations of the above embodiment described with reference to FIG. 6, FIG. 8 and FIG. 9.

According to this embodiment, as shown in FIGS. 10-12, no backlight or incident light polarizer is required in the display unit 7, and a light emitted from the organic light-emitting diode display panel may be polarized by the emergent light polarizer 2 and/or the wave plate 3, thereby realizing the purpose of dual-field display.

Similar to the above embodiment, the dual-field display system according to this embodiment may also be in many different forms.

As shown in FIG. 10 (similar to the implementation of the above embodiment described with reference to FIG. 6), outside the light exiting surface of the display panel 1, a first emergent light polarizer 21 and a second emergent light polarizer 22 having different polarization directions may be provided within different display regions, and the first glasses 81 and the second glasses 82 having corresponding linear polarizers may be coordinately employed.

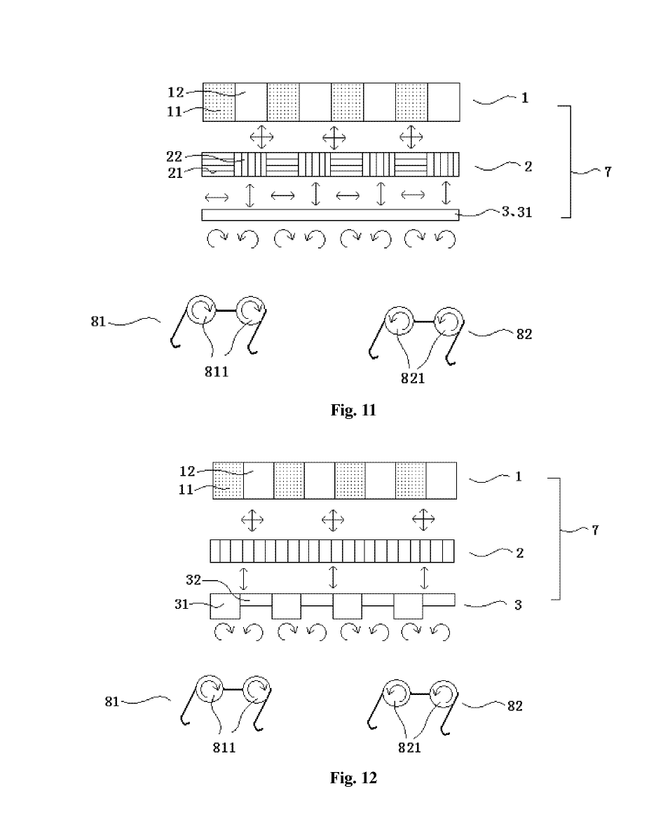

Alternatively, as shown in FIG. 11 (similar to the implementation of the above embodiment described with reference to FIG. 8), the wave plate 3 may be provided outside the emergent light polarizer 2 to generate circular polarized light having opposite rotation directions (i.e., polarized light having different polarization directions), and the first glasses 81 and the second glasses 82 having corresponding linear polarizers may be employed.

Alternatively, as shown in FIG. 12 (similar to the implementation of the above embodiment described with reference to FIG. 9), the polarization direction of the emergent light polarizer 2 is identical, but the wave plate 3 includes a ¼ wave plate 31 and a ¾ wave plate 32 in two different forms.

It should be understood that the foregoing implementations are merely exemplary implementations for describing the principle of the present invention, but the present invention is not limited thereto. A person of ordinary skill in the art may make various variations and improvements without departing from the spirit and essence of the present invention, and these variations and improvements are also deemed as falling into the protection scope of the present invention.

1-11. (canceled)

12. A dual-field display system, comprising:
a display unit including a display panel divided into a first display region and a second display region, the first display region emitting a first polarized light with a first polarization direction, the second display region emitting a second polarized light with a second polarization direction different from the first polarization direction;
at least one pair of first glasses comprising a left lens and a right lens, the left lens and the right lens of the first glasses each comprising a first polarizer for allowing the first polarized light to transmit therethrough and blocking the second polarized light; and
at least one pair of second glasses comprising a left lens and a right lens, the left lens and the right lens of the second glasses each comprising a second polarizer for allowing the second polarized light to transmit therethrough and blocking the first polarized light.

13. The dual-field display system according to claim 12, wherein the display unit further comprises:
an emergent light polarizer provided outside a light exiting surface of the display panel and comprising a first emergent light polarizer and a second emergent light polarizer, the first emergent light polarizer being provided within the first display region and having a first emergent polarization direction, the second emergent light polarizer being provided within the second display region and having a second emergent polarization direction, the first emergent polarization direction being vertical to the second emergent polarization direction, wherein
both of the first polarizer and the second polarizer are linear polarizer, the polarization direction of the first polarizer is parallel to the first emergent polarization direction, and the polarization direction of the second polarizer is parallel to the second emergent polarization direction.

14. The dual-field display system according to claim 12, wherein the display unit further comprises:
an emergent light polarizer provided outside a light exiting surface of the display panel and comprising a first emergent light polarizer and a second emergent light polarizer, the first emergent light polarizer being provided within the first display region and having a first emergent polarization direction, the second emergent light polarizer being provided within the second display region and having a second emergent polarization direction, the first emergent polarization direction being vertical to the second emergent polarization direction; and
a wave plate provided outside the emergent light polarizer, the wave plate being a ¼ wave plate or a ¾ wave plate, both of the included angle between the optical axis of the wave plate and the first emergent polarization direction and the included angle between the optical axis of the wave plate and the second emergent polarization direction being 45 degree, wherein
one of the first polarizer and the second polarizer is a left-handed circular polarizer, and the other one of the first polarizer and the second polarizer is a right-handed circular polarizer.

15. The dual-field display system according to claim 12, wherein the display unit further comprises:
an emergent light polarizer provided outside a light exiting surface of the display panel; and
a wave plate provided outside the emergent light polarizer and comprising a ¼ wave plate and a ¾ wave plate, the ¼ wave plate being provided within one of the first display region and the second display region, the ¾ wave plate being provided within the other one of the first display region and the second display region, the included angles between the optical axes of the wave plates and the polarization direction of the emergent light polarizer being 45 degree, wherein
one of the first polarizer and the second polarizer is a left-handed circular polarizer, and the other one of the first polarizer and the second polarizer is a right-handed circular polarizer.

16. The dual-field display system according to claim 12, wherein the display panel is a liquid crystal display panel, and the display unit further comprises a backlight and an incident light polarizer, wherein
the backlight is provided outside a light receiving surface of the liquid crystal display panel, and the incident light polarizer is provided between the backlight and the liquid crystal display panel.

17. The dual-field display system according to claim 16, wherein the incident light polarizer comprises a first incident light polarizer and a second incident light polarizer, the first incident light polarizer being provided within the first display region and having a first incident polarization direction, the second incident light polarizer being provided within the second display region and having a second incident polarization direction, and the first incident polarization direction being vertical to the second incident polarization direction.

18. The dual-field display system according to claim 13, wherein the display panel is an organic light-emitting diode display panel.

19. The dual-field display system according to claim 12, wherein,
the first display region comprises a plurality of parallel first strip-shaped sub-regions, and the second display region comprises a plurality of parallel second strip-shaped sub-regions, wherein
the plurality of first strip-shaped sub-regions and the plurality of second strip-shaped sub-regions are arranged alternately in parallel to each other.

20. The dual-field display system according to claim 19, wherein, the length direction of the first strip-shaped sub-regions and the second strip-shaped sub-regions is parallel to the row direction of the display panel; or
the length direction of the first strip-shaped sub-regions and the second strip-shaped sub-regions is parallel to the column direction of the display panel.

21. The dual-field display system according to claim 19, wherein,
the length direction of the first strip-shaped sub-regions and the second strip-shaped sub-regions is parallel to the row direction of the display panel, and each of the first strip-shaped sub-regions and the second strip-shaped sub-regions is a row of pixels of the display panel; or
the length direction of the first strip-shaped sub-regions and the second strip-shaped sub-regions is parallel to the column direction of the display panel, and each of the first strip-shaped sub-regions and the second strip-shaped sub-regions is a column of pixels of the display panel.

22. The dual-field display system according to claim 12, wherein,
the first display region comprises a plurality of first rectangular sub-regions, and the second display region comprises a plurality of second rectangular sub-regions, wherein
the first rectangular sub-regions and the second rectangular sub-regions are the same in size, and the first rectangular sub-regions and the second rectangular sub-regions are arranged into a matrix,
in each row of the matrix, the first rectangular sub-regions and the second rectangular sub-regions are arranged alternately, and
in each column of the matrix, the first rectangular sub-regions and the second rectangular sub-regions are arranged alternately.

23. The dual-field display system according to claim 13, wherein the display panel is a liquid crystal display panel, and the display unit further comprises a backlight and an incident light polarizer, wherein
the backlight is provided outside a light receiving surface of the liquid crystal display panel, and the incident light polarizer is provided between the backlight and the liquid crystal display panel.

24. The dual-field display system according to claim 23, wherein the incident light polarizer comprises a first incident light polarizer and a second incident light polarizer, the first incident light polarizer being provided within the first display region and having a first incident polarization direction, the second incident light polarizer being provided within the second display region and having a second incident polarization direction, and the first incident polarization direction being vertical to the second incident polarization direction.

25. The dual-field display system according to claim 14, wherein the display panel is a liquid crystal display panel, and the display unit further comprises a backlight and an incident light polarizer, wherein
the backlight is provided outside a light receiving surface of the liquid crystal display panel, and the incident light polarizer is provided between the backlight and the liquid crystal display panel.

26. The dual-field display system according to claim 25, wherein the incident light polarizer comprises a first incident light polarizer and a second incident light polarizer, the first incident light polarizer being provided within the first display region and having a first incident polarization direction, the second incident light polarizer being provided within the second display region and having a second incident polarization direction, and the first incident polarization direction being vertical to the second incident polarization direction.

27. The dual-field display system according to claim 15, wherein the display panel is a liquid crystal display panel, and the display unit further comprises a backlight and an incident light polarizer, wherein
the backlight is provided outside a light receiving surface of the liquid crystal display panel, and the incident light polarizer is provided between the backlight and the liquid crystal display panel.

28. The dual-field display system according to claim 27, wherein the incident light polarizer comprises a first incident light polarizer and a second incident light polarizer, the first incident light polarizer being provided within the first display region and having a first incident polarization direction, the second incident light polarizer being provided within the second display region and having a second incident polarization direction, and the first incident polarization direction being vertical to the second incident polarization direction.

29. The dual-field display system according to claim 14, wherein the display panel is an organic light-emitting diode display panel.

30. The dual-field display system according to claim 15, wherein the display panel is an organic light-emitting diode display panel.
